(19) United States
(12) Patent Application Publication
(10) Pub. No.: US 2024/0136279 A1
(43) Pub. Date: Apr. 25, 2024

(54) INTEGRATED INDUCTOR OVER TRANSISTOR LAYER

(71) Applicant: Intel Corporation, Santa Clara, CA (US)

(72) Inventors: Min Suet Lim, Gelugor (MY); Telesphor Kamgaing, Chandler, AZ (US); Chee Kheong Yoon, Beyan Lepas (MY); Chu Aun Lim, Hillsboro, OR (US); Eng Huat Goh, Penang (MY); Jooi Wah Wong, Bukit Mertajam (MY); Kavitha Nagarajan, Bangalore KA (IN)

(73) Assignee: Intel Corporation, Santa Clara, CA (US)

(21) Appl. No.: 17/972,975

(22) Filed: Oct. 24, 2022

(51) Int. Cl. H01L 23/522; H01L 49/02

(52) U.S. Cl. CPC H01L 23/5227; H01L 28/10

(57) ABSTRACT

Described herein are integrated circuit devices that include semiconductor devices near the center of the device, rather than towards the top or bottom of the device, and integrated inductors formed over the semiconductor devices. Power delivery to the device is on the opposite side of the semiconductor devices. The integrated inductors may be used for power step-down to reduce device thickness and/or a number of power rails.

### BACKGROUND

Integrated circuit (IC) devices receive power from external sources. IC devices are being developed that include greater numbers of processing cores and demand greater power. The power demands can increase the number of external power rails and on-device power circuitry, which increases device thickness.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example IC architecture with dummy layers over semiconductor device and interconnect layers, according to some embodiments of the present disclosure.

FIG. 2 illustrates an example IC device with one or more integrated inductors over the device layer(s), according to some embodiments of the present disclosure.

FIGS. 3, 4, and 5 illustrate three example cross-sections of ICs device having a device layer, interconnect layers, and integrated inductors, according to some embodiments of the present disclosure.

FIGS. 6A through 6J illustrate a process for forming an IC device with integrated inductors, according to some embodiments of the present disclosure.

FIGS. 7A and 7B are top views of, respectively, a wafer and dies that may include one or more integrated inductors in accordance with any of the embodiments disclosed herein.

FIG. 8 is a cross-sectional side view of an IC package that may include one or more integrated inductors in accordance with any of the embodiments disclosed herein.

FIG. 9 is a cross-sectional side view of an IC device assembly that may include one or more integrated inductors in accordance with any of the embodiments disclosed herein.

FIG. 10 is a block diagram of an example computing device that may include one or more integrated inductors in accordance with any of the embodiments disclosed herein.

### DETAILED DESCRIPTION

Overview

Power delivery is an important challenge in semiconductor devices. Increasing power to a chip can provide greater power and performance, but requires a greater volume of on-chip circuitry to connect to a power source and deliver the power across the device. For example, power delivery at higher voltages may require thicker copper wiring than lower voltages, and the thicker wiring increases device form factor. As another example, new designs may add more power rails to a package to provide increased power, including distributed rails at different voltage levels. These power rail arrangements can provide greater efficiency at higher power demands; however, additional power rails require device space that can increase the size and, particularly, the thickness of the device package. Thus, there is a trade-off between power delivery capabilities and device size.

In some previous IC arrangements, semiconductor devices (e.g., transistors) are formed over a substrate, and interconnect structures are formed over the semiconductor devices. Power and signal delivery may extend from the opposite side of the IC (e.g., the back side of the IC) and through the interconnect structures. In this arrangement, passive devices for power management, including inductors, are typically formed on the power and signal delivery side of the IC (the back side of the IC).

Another IC architecture positions semiconductor devices nearer to the middle of the package. Interconnect structures may be formed both above and below the semiconductor devices. This architecture can improve power and signal delivery, e.g., by allowing power delivery from one side (e.g., the back side of the semiconductor devices), and signal delivery from the other side (e.g., the front side of the semiconductor devices). As another example, power delivery and signal input/output (I/O) may be on one side of the device layers (e.g., on a back side), while transfer of signals between components (e.g., between different processing units) in the package may be routed through interconnects on the opposite side of the device layers (e.g., on a front side).

When the transistors are in the middle of the IC, in some cases, dummy layers may be included over the front side of the semiconductor device layer(s), opposite the power and signal I/O. In the fabrication of an IC, the number of interconnect layers, also referred to as metal layers, formed over the semiconductor devices may be fixed across multiple device designs. If a particular IC design does not utilize all of the layers, a dummy region is fabricated. The dummy region includes an insulating material, and may include metal portions that are not connected to other layers.

Embodiments of the present disclosure may improve on at least some of the challenges and issues described above by providing one or more integrated inductors over the semiconductor devices, e.g., over a front side of a semiconductor device layer. The integrated inductor may utilize unused space in the dummy layers. For example, the integrated inductor may receive a first voltage (e.g., an input power) and step the voltage down to a second, lower voltage used by certain circuitry on the chip. Including integrated inductors for voltage step-down reduces the number of power rails out to the platform, e.g., enabling a single input power rail. The integrated inductor can also reduce extra package layers below the semiconductor device layers, thus enabling a thinner form factor. In some embodiments, the inductors can be conductive structures (e.g., conductive coils) embedded in or otherwise surrounding a ferroelectric material, which results in increased inductance relative to inductors that are formed around dielectric materials. The inductors may be arranged so that the coils are substantially parallel to the device layer or substantially perpendicular to the device layer.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

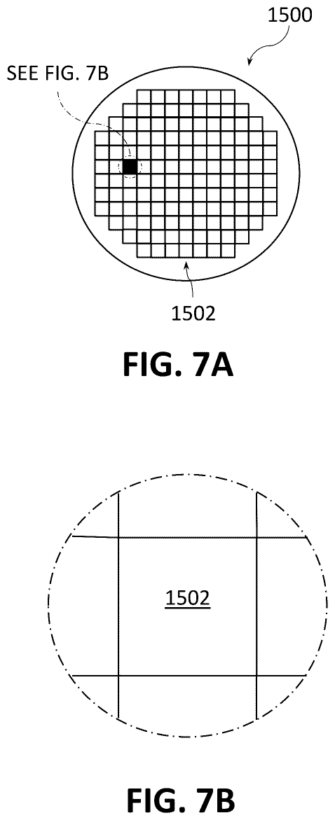

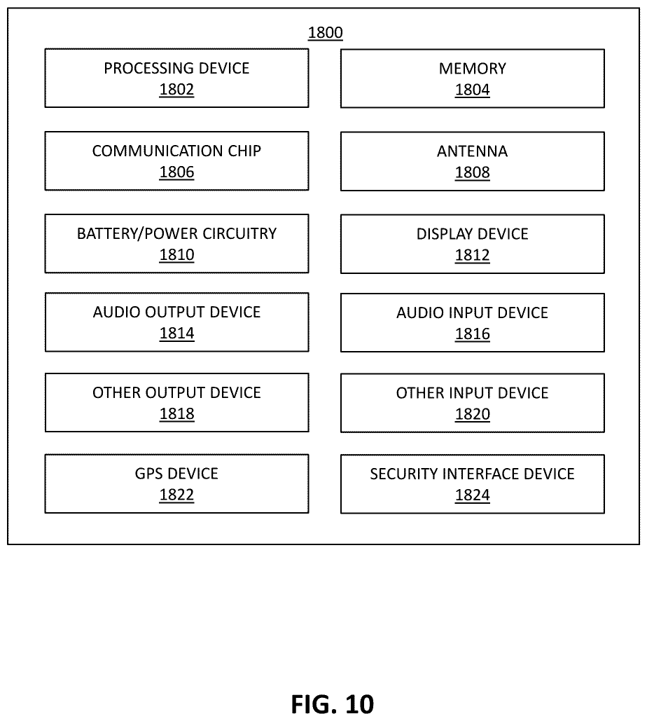

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 10.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with integrated inductors as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example IC with Dummy Region Over Device Layer

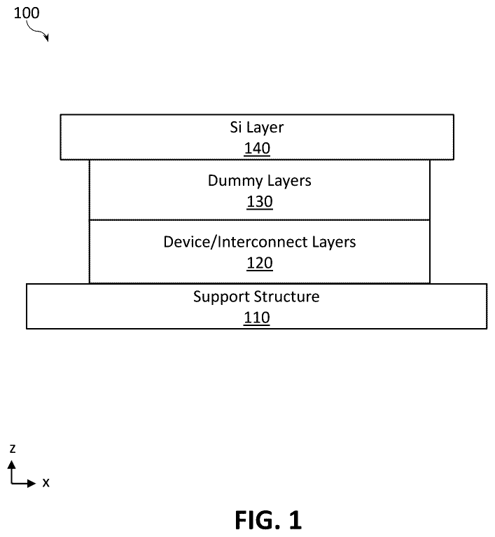

FIG. 1 illustrates an example IC architecture with dummy layers over semiconductor device and interconnect layers. An IC device 100 includes a support structure 110, device and interconnect layers 120 over the support structure 110, and dummy layers 130 over the device and interconnect layers 120. The IC device 100 further includes a silicon layer 140 over the dummy layers 130.

The device and interconnect layers 120 include a set of interconnect layers over the support structure 110. These interconnect layers may enable power and signal delivery to the IC device 100. The interconnect layers may also enable intra-device communication. One or more device layers including semiconductor devices (e.g., transistors) are over the interconnect layers. In some cases, additional interconnect layers may be over the device layer(s). Dummy layers 130 are over the device and interconnect layers 120. The dummy layers 130 may be directly over a device layer, or a portion of a device layer. Alternatively, a dummy layer 130, or a portion of a dummy layer 130, may be over an interconnect layer.

In this arrangement, the device (transistor) layer(s) are neither at the top nor the bottom of the IC device 100. The dummy layers 130 sit between the device layer(s) and the silicon layer 140, and are unused space in the device 100. In the arrangement shown in FIG. 1, the IC device 100 may further include circuitry for input and delivery of power on the backside of the device, e.g., below the support structure 110, or between the support structure 110 and the device/interconnect layers 120. The power circuitry may include multiple inputs for different voltage levels, one or more inductors, and multiple power rails for transferring power within the device 100.

Example ICs with Integrated Inductor(s) Over Device Layer

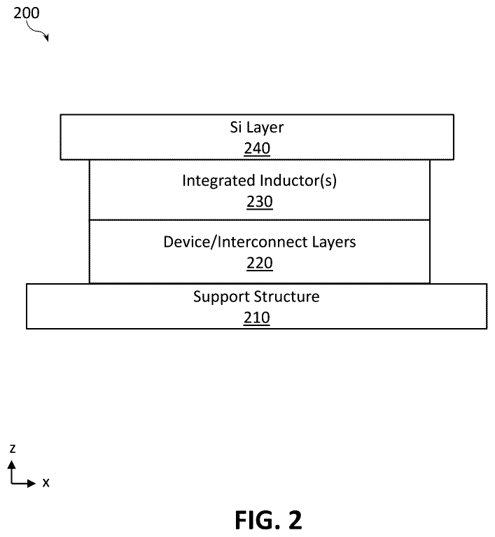

FIG. 2 illustrates an example IC device with one or more integrated inductors over the device layer(s), according to some embodiments of the present disclosure. The IC device 200 includes a support structure 210, device and interconnect layers 220 over the support structure 210, and integrated inductor(s) 230 over the device and interconnect layers 220. The integrated inductor(s) 230 replace some or all of the dummy layers 130 shown in FIG. 1. The IC device 200 further includes a silicon layer 240 over the integrated inductor(s) 230. The integrated inductor(s) 230 are formed from conductive (e.g., metal) coils built in the metallization layers. The integrated inductors 230 may be embedded in a ferroelectric material, such as cobalt or cadmium zinc telluride (CZT). The integrated inductor(s) 230 may be electrically coupled to a power source, e.g., through back side interconnects and additional interconnects in the device and interconnect layers 220.

The support structure 210 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which an IC device as described herein may be built falls within the spirit and scope of the present disclosure. The silicon layer 240 may be similar to the support structure 210 described above. In some embodiments, a different material than silicon may be used over the integrated inductor(s) 230. Additional components, such as a heat spreader formed over and/or around the device, or one or more additional layers not illustrated in FIG. 2 may be included.

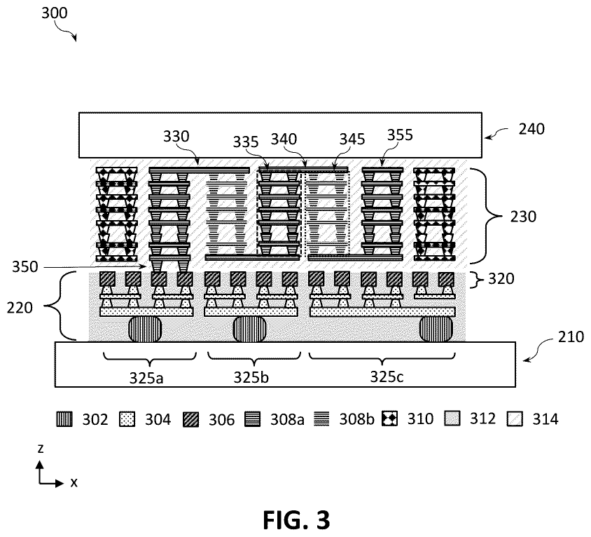

FIGS. 3, 4, and 5 illustrate three example cross-sections of the IC device 200, each having a device layer, interconnect layers, and integrated inductors, according to some embodiments of the present disclosure. FIGS. 3-5 illustrates the device/interconnect layers 220 and integrated inductors 230 in greater detail, with different embodiments of the integrated inductors 230. A number of elements referred to in the description of FIGS. 3 through 6J with reference numerals are illustrated in these figures with different patterns, with a legend showing the correspondence between the reference numerals and patterns being provided at the bottom of the drawing pages.

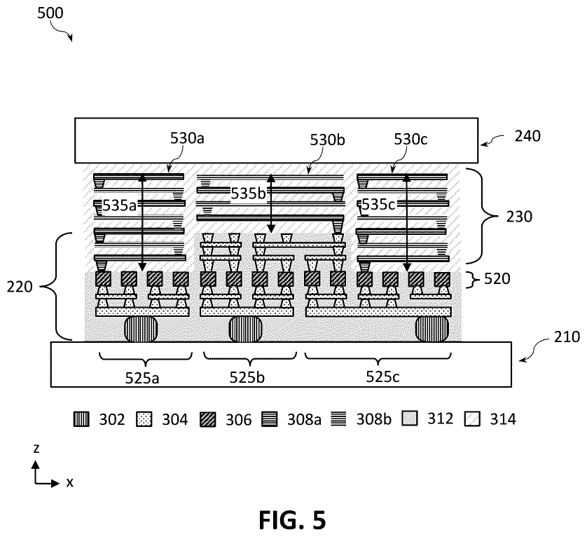

Turning first to FIG. 3, the device/interconnect layers 220 include solder balls 302, interconnect structures 304, and transistors 306. The transistors 306 are arranged in a device layer 320. While a single device layer 320 is illustrated in FIG. 3, the IC device 200 may include multiple device layers at different heights in the z-direction. In this example, the interconnect structures 304 are illustrated as being under a back side of the device layer 320. In other embodiments, interconnect structures 304 providing signal and/or power transfer across the device layer 320 may also be formed over a front side of the device layer 320. An example with front side interconnects is shown in FIG. 5.

The device/interconnect layers 220 include three different regions 325a, 325b, and 325c, where different regions are located at different positions along the x-axis in the coordinate system shown. The different regions 325a, 325b, and 325c may correspond to different sub-devices with different functionalities. For example, the region 325a may be a central processing unit (CPU), the region 325c may be a graphical processing unit (GPU), and the region 325b may be a communications interface providing input and output for the IC device 300. In other embodiments, different regions may be associated with different functionalities. For example, other regions may include memory, digital signal processors (DSPs), various types of communications interfaces, other types of processors, etc.

The computing regions 325a, 325b, and 325c are formed over interconnect layers that include a metallization stack and one or more solder balls 302. The solder balls 302 provide electrical and mechanical contact to the support structure 210, which may be in turn be coupled to other external components, e.g., for input and output of signals, and input of power to the IC device 200. The IC device 300 may have other alternative configurations to route electrical signals from the device/interconnect layers 220 and out of the IC device 300. For example, the solder balls 302 may be replaced by or may further include other analogous features (e.g., posts) that route the electrical signals to external components.

The interconnects 304 form layers of a metallization stack, where each layer may include an insulating material 312, which is a dielectric material formed in multiple layers, as known in the art. The interconnects 304 may include one or more conductive traces and conductive vias, providing one or more conductive pathways through the insulating materials. The interconnects 304 may be formed from appropriate conductive material, such as copper, silver, nickel, gold, aluminum, or other metals or alloys, for example. The conductive pathways may be connected to one another in any suitable manner. While all of the interconnects 304 in FIG. 3 are illustrated as being formed form the same material, in other embodiments, different materials may be used, e.g., the interconnects over a front side of the device layer 320 may include a different material from the interconnects below the back side of the device layer 320. Although FIG. 3 illustrate a specific number and arrangement of conductive pathways formed by the interconnects 304, these are simply illustrative, and any suitable number and arrangement may be used.

In some embodiments, the insulating material 312 surrounding the interconnects 304 and/or the transistors 306 may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imagable dielectrics, and/or benzocyclobutene-based polymers). In some embodiments, the insulating material 312 may include a semiconductor material, such as silicon, germanium, or a III-V material (e.g., gallium nitride), and one or more additional materials. For example, the insulating material may include silicon oxide or silicon nitride. An insulating material in the device layer 320 may be different from insulating materials around the interconnects 304 above and/or below the device layer 320.

The interconnects 304 form conductive pathways to route power, ground, and/or signals to/from various components of the device layer 320. The device layer 320 includes logic devices, e.g., transistors 306, coupled to the interconnect 304, e.g., through conductive contacts. The device layer 320 may include semiconductor material systems including, for example, N-type or P-type materials systems, as active materials (e.g., as channel materials of transistors). In some embodiments, the transistors 306 may include substantially monocrystalline semiconductors, such as silicon or germanium.

In some embodiments, the transistors 306 may include compound semiconductors, e.g., compound semiconductors with a first sub-lattice of at least one element from group III of the periodic table (e.g., Al, Ga, In), and a second sub-lattice of at least one element of group V of the periodic table (e.g., P, As, Sb). In some embodiments, the transistors 306 may include a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

In some embodiments, the transistors 306 may be/include an intrinsic IV or III-V semiconductor material or alloy, not intentionally doped with any electrically active impurity. In alternate embodiments, nominal impurity dopant levels may be present within the transistors 306, for example to set a threshold voltage Vt, or to provide halo pocket implants, etc. In such impurity-doped embodiments however, impurity dopant level within the active materials may be relatively low, for example below about 10¹⁵ cm⁻³, and advantageously below 10¹³ cm⁻³.

For exemplary P-type transistor embodiments, transistors 306 may advantageously be formed using group IV materials having a high hole mobility, such as, but not limited to, Ge or a Ge-rich SiGe alloy. For some exemplary embodiments, such active materials may have a Ge content between 0.6 and 0.9, and advantageously is at least 0.7.

For exemplary N-type transistor embodiments, the transistors 306 may advantageously be formed using a III-V material having a high electron mobility, such as, but not limited to InGaAs, InP, InSb, and InAs. For some such embodiments, the active material may be a ternary III-V alloy, such as InGaAs or GaAsSb. For some InₓGa₁₋ₓAs fin embodiments, In content in the such active material may be between 0.6 and 0.9, and advantageously at least 0.7 (e.g., In_{0.7}Ga_{0.3}As).

In some embodiments, the transistors 306 may be formed from thin-film materials, in which embodiments the transistors 306 could be thin-film transistors (TFTs). A TFT is a special kind of a field-effect transistor (FET), made by depositing a thin film of an active semiconductor material, as well as a dielectric layer and metallic contacts, over a support structure that may be a non-conducting (and non-semiconducting) support structure. During operation of a TFT, at least a portion of the active semiconductor material forms a channel of the TFT, and, therefore, the thin film of such active semiconductor material is referred to herein as a “TFT channel material.” This is different from conventional, non-TFT, transistors where the active semiconductor channel material is typically a part of a semiconductor substrate, e.g., a part of a silicon wafer. In various such embodiments, active materials of the transistors 306 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

In general, active materials of the transistors 306 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

The integrated inductor region 230 includes an inductor 330. The inductor 330 includes conductive material 308 formed in a coil. FIG. 3 uses different patterns to illustrate the conductive material 308a, which is in the plane of the cross-section, and a conductive material 308b, which is out of the plane of the cross-section. The conductive material 308b is at a different position along the y-axis in the coordinate system shown, e.g., further into the page than the conductive material 308a. The conductive materials 308a and 308b may be the same material, but are illustrated differently to distinguish the out-of-plane material 308b from the in-plane material 308a.

The inductor 330 is formed in metallization layers over the device layer 320. In this example, the sides of the inductor 330 extend substantially in the y-direction and z-direction in the coordinate system shown. A stack of vias and short trenches are stacked in the z-direction, forming one set of sides of an inductor. For example, the stack 335, including the vias and trenches bounded by the dotted box, forms one side of an inductive coil. While the stack 335 is illustrated as including a pair of vias in each metallization layer coupled to a short trench, in other embodiments, the side of an inductor may be formed from a single stack of vias, or a stack of three or more adjacent vias.

Trench structures extending in the y-direction form additional sides of the inductor 330. For example, the trench 340 extends into the plane in the y-direction, coupling the stack 335 to the stack 345, which is at a different position along the y-axis from the stack 335. The trench structures are substantially perpendicular to the sides formed from vias, e.g., the stacks 335 and 345. The trench sides, e.g., trench 340, are substantially parallel to a front side of the device layer 320. The stacked sides, e.g., sides 335 and 345, are substantially perpendicular to the front side of the device layer 320.

In this example, one end 350 of the inductor 330 is coupled to the device layer 320, and in particular, to a set of transistors 306 in the device layer 320. In other embodiments, the end 350 of the inductor may be coupled to a conductive interconnect extending through the device layer 320, e.g., to receive an input power from the interconnect layers. The other end 355 of the inductor 330 may be coupled to, e.g., an input power (e.g., an input power received at a solder ball 302), to an internal power rail, to the device layer 320, etc. For example, as described above, the inductor 330 may provide voltage step-down, e.g., receiving an input first voltage, and stepping down the voltage amplitude to an output second voltage less than the input first voltage.

In this example, dummy interconnects 310 are also formed at the edges or sides of the device 300. The dummy interconnects 310 are not part of the inductor 330, and the dummy interconnects 310 are not electrically or physically connected to the inductor 330 or the device layer 320. In other embodiments, dummy interconnects 310 may be omitted. For example, the inductor 330 may extend into the region of the dummy interconnects 310.

The inductor 330 and, in this example, the dummy interconnects 310 are embedded in a ferroelectric material 314. Thus, the ferroelectric material 314 is inside of the inductor 330 (and, in this case, also outside of the inductor 330), and the inductor 330 is coiled around ferroelectric material 314. The ferroelectric material may be, for example, cobalt or CZT. Embedding the inductor 330 in a ferroelectric material results in a greater inductance than if the inductor 330 surrounds an insulating material. In other embodiments, the inductor 330 may instead surround an insulating material, such as the materials described with respect to the insulating material 312.

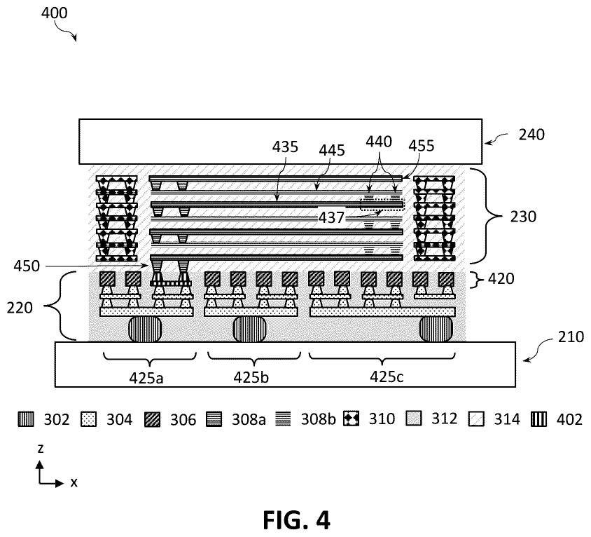

FIG. 4 includes device/interconnect layers 220 similar to those illustrated in FIG. 3 and described above. The transistors 306 are arranged in a device layer 420. In this example, the device layer 420 includes conductive material 402 formed through a portion of the device layer 420, coupling the interconnects 304 to one end 450 of the inductor 430.

The integrated inductor region 230 illustrated in FIG. 4 includes an inductor 430. The inductor 430 includes conductive material 308 formed in a coil. FIG. 4 uses the same patterns 308a and 308b as in FIG. 3 to illustrate conductive material in the illustrated plane (308a) and out of the illustrated plane (308b). The conductive material 308b is at a different position along the y-axis in the coordinate system shown, e.g., at a plane further into the page.

The inductor 430 is formed in metallization layers over the device layer 420. In this example, the sides of the inductor 430 extend substantially in the x-direction and y-direction in the coordinate system shown. Vias extending in the z-direction connect portions of the inductor 430 formed in different metallization layers. For example, the trench 435 forms one side of an inductive coil extending in the x-direction. One end of the trench 435, surrounded by the dashed box 437, is coupled a trench extending in the y-direction (e.g., into the page), perpendicular to the trench 435. The trench structures forming the sides of the inductor 430 are substantially parallel to a front side of the device layer 320.

The far end of the trench extending in the y-direction is coupled to a pair of vias 440, which are also coupled to another trench 445 extending in the x-direction, forming another side of the inductor. While pairs of vias (e.g., the pair 440) are illustrated as connecting trenches in different metallization layers, in other embodiments, a single via, or three or more adjacent vias, may be used to couple trenches in different metallization layers to form the inductor 430.

As noted above, in this example, one end 450 of the inductor 430 is coupled to the interconnect 304 via conductive structures 402 in the device layer 320. For example, the end 450 may receive an input power from the interconnect layers, which may be an input power received at one of the solder balls 302. The other end 455 of the inductor 430 may be an output power that is coupled to, e.g., an internal power rail and/or to the device layer 420.

Like FIG. 3, this example includes dummy interconnects 310 formed at the edges or sides of the device 400. The dummy interconnects 310 are not part of the inductor 430, and the dummy interconnects 310 are not electrically or physically connected to the inductor 430 or the device layer 420. In other embodiments, the dummy interconnects 310 may be omitted. For example, the inductor 430 may extend into the region of the dummy interconnects 310. The inductor 430 and, in this example, the dummy interconnects 310 are embedded in a ferroelectric material 314, as described with respect to FIG. 3.

FIG. 5 includes a different embodiment of the device/interconnect layers 220 from FIGS. 3 and 4, and includes multiple inductors formed over different regions of the device/interconnect layers 220. Different regions of the device/interconnect layers 220 have different heights, where height refers to a dimension in the z-direction in the coordinate system shown. The transistors 306 are arranged in a device layer 520, similar to the device layer 320. Interconnect 304 and solder balls 302 below the device layer 320 are also similar to the interconnect and solder balls described with respect to FIG. 3. In this case, unlike in FIGS. 3 and 4, a central region of the device/interconnect layers 220, corresponding to the region 525b and a portion of 525c, has several interconnect layers formed over the device layer 520. The interconnect layers formed over the device layer 520 may provide interconnections between the communications interface and the GPU in the example described above. In other embodiments, different regions may also have transistors 306 formed in various layers at various heights, rather than a single layer 520 extending across the device 500.

The integrated inductor region 230 illustrated in FIG. 5 includes three inductors 530a, 530b, and 530c. Each inductor 530a, 530b, 530c includes conductive material 308 formed in a coil. FIG. 5 uses the same patterns 308a and 308b as in FIG. 3 to illustrate conductive material in (308a) and out of (308b) the plane of the cross-section. The conductive material 308b is at a different position along the y-axis in the coordinate system shown, e.g., at a plane further into the page. Each of the inductors 530 is formed in metallization layers over a corresponding region of the device layer 520. In this example, the sides of the inductors 530 extend substantially in the x-direction and y-direction in the coordinate system shown, and vias extending in the z-direction connect portions of the inductor 530 formed in different metallization layers, as described above with respect to FIG. 4.

Different ends of each of the inductors 530a, 530b, and 530c may be coupled to interconnect 304, power rails, input power supplies, transistors 306, etc., as described with respect to FIGS. 3 and 4.

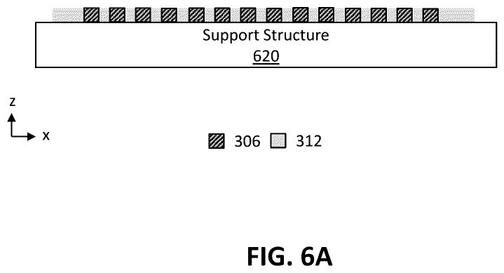

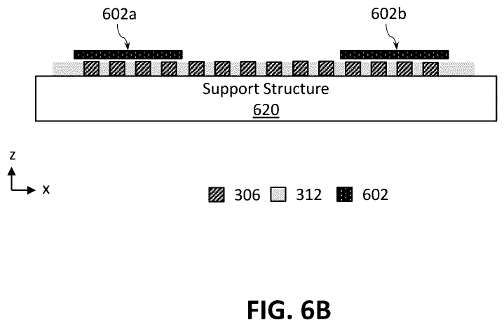

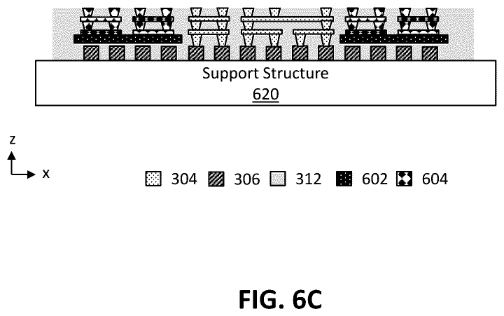

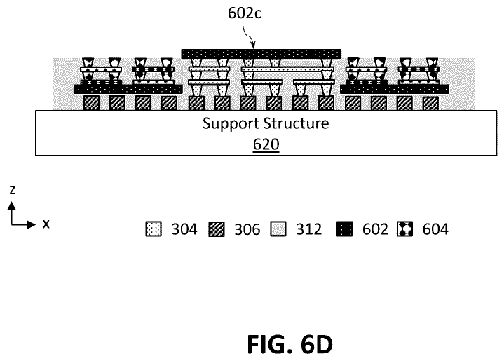

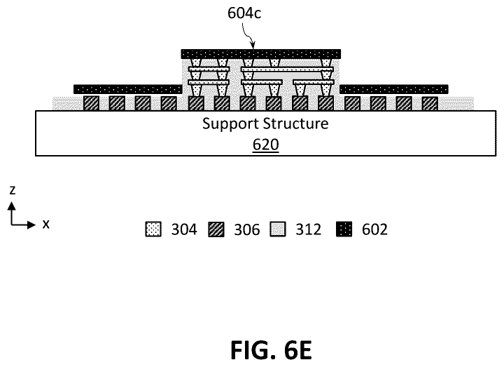

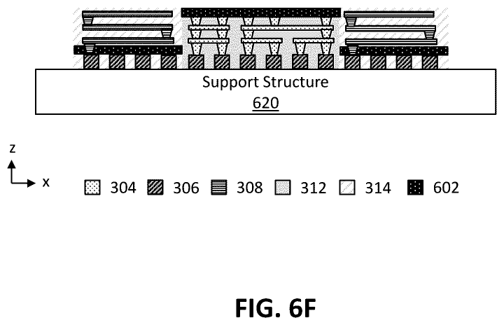

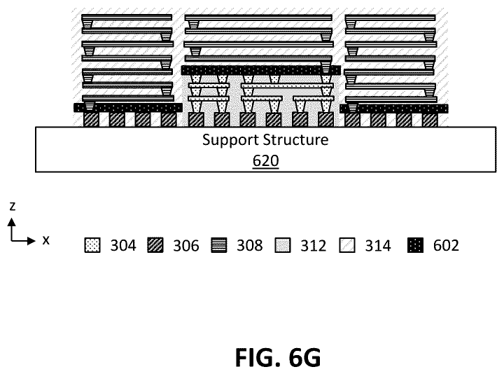

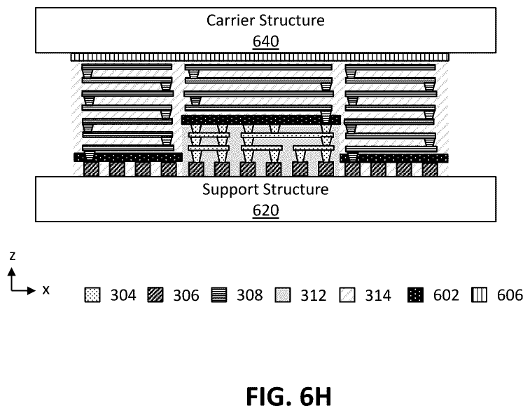

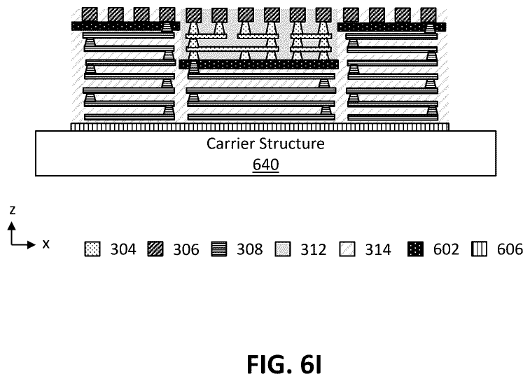

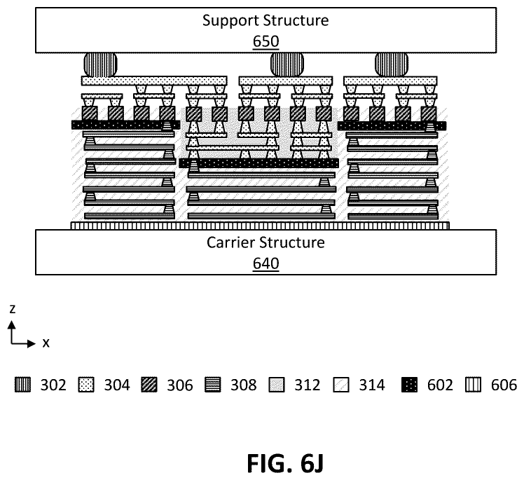

The inductors 530a, 530b, and 530c have corresponding heights 535a, 535b, and 535c illustrated in FIG. 5. The inductors 530a and 530c formed directly over the device layer 520 are taller than the inductor 530b, which is formed over the interconnect region formed over the front side of the device layer 520. A method for fabricating an IC device with inductors having different heights is described with respect to FIG. 6.

This example does not include dummy interconnects 310, but in other embodiments, dummy interconnects may be included. The inductors 530a, 530b, and 530c are embedded in a ferroelectric material 314, as described with respect to FIG. 3. In this example, the ferroelectric material 314 has different thicknesses (a dimension in the z-direction) based on the heights of the inductors 530a, 530b, and 530c.

Example Process for Forming IC with Integrated Inductor(s) Over Device Layer

FIGS. 6A through 6J illustrate a process for forming an IC device with integrated inductors, according to some embodiments of the present disclosure. While FIGS. 6A through 6J illustrate fabrication of an IC with three inductors, a similar process may be used to fabricate an IC with more or fewer inductors, and/or inductors having a different orientation from the inductors shown in FIG. 6.

FIG. 6A illustrates a device layer having transistors 306 formed over a support structure 620. The transistors 306 may include any of the materials described above with respect to FIG. 3. The transistors 306 are surrounded by a dielectric material 312, which may include any of the dielectric materials described with respect to FIG. 3. The support structure 620 may be similar to the support structure 210 described with respect to FIG. 2. While not illustrated in FIG. 6A, in some embodiments, one or more metallization layers with interconnect structures are formed across a front side the transistors 306, i.e., across the top side opposite the support structure 620.

In FIG. 6B, a layer of an etch stop 404 has been deposited over a portion of the device layer. As noted above, the etch stop 404 may be deposited over transistors 306 and any interconnect layers formed over the transistors 306, e.g., source, drain, and/or gate contacts, and interconnects for routing signals to the contacts on the front side of the transistors 306.

In this example, the etch stop 602 is arranged in two regions 602a and 602b over the device layer. The etch stop 602 may be deposited using any suitable process for depositing a material over selected regions of the device. For example, any suitable lithographic process may be used in combination with a suitable etching process. In various embodiments, suitable lithographic processes may include photolithography, electron-beam lithography, etc., which may be used to define locations and dimensions for removing portions of a layer of etch stop, leaving behind the etch stop regions 602a and 602b. In various embodiments, suitable etching processes may include dry etch, wet etch, etc., which may be used to remove portions of the etch stop in regions defined by the lithographic process so that the regions 602a and 602b remain.

In FIG. 6C, interconnect 304 is formed over the etch stop 602 and the exposed transistors 306, i.e., the transistors not covered by the etch stop 602. This interconnect 304 corresponds to the interconnect formed over the device layer 520 in FIG. 5. In addition to the interconnect 304, dummy interconnect structures 604 are formed over the etch stop 602. The dummy interconnect 604 may include the same materials as the interconnect 304 but is not electrically coupled to other parts of the device (e.g., the dummy interconnect 604 is not coupled to the interconnect 304 or the transistors 306). In other embodiments, the dummy interconnect 604 may be formed from a different material from the interconnect 304.

The interconnect 304 and dummy interconnect 604 are surrounded by the dielectric material 312. As noted above, in some embodiments, the dielectric material 312 around the transistors 306 may be different from the dielectric material around the interconnect 304 and dummy interconnect 604. The interconnect 304 and dummy interconnect 604 may be formed using processes for patterning and depositing interconnect as are known in the art.

At FIG. 6D, another layer of an etch stop 602 is deposited over the interconnect 304. This etch stop region, labelled 602c, may be deposited in a similar manner as the etch stop regions 602a and 602b, e.g., using a lithographic process to cause the etch stop 602 to cover the interconnect 304 but not the dummy interconnect 604. While the etch stop region 602c is illustrated with the same pattern as the etch stop regions 602a and 602b, in other embodiments, different materials may be used.

At FIG. 6E, the dummy interconnect 604 is removed, e.g., through one or more etching processes. Removal of the dummy interconnect 604 leaves the interconnect 304 and transistors 306 intact, due to the etch stop 602.

At FIG. 6F, layers of the inductors 530a and 530c are formed over the etch stop regions 602a and 602b. The conductive material 308 is formed in a ferroelectric material 314, as described with respect to FIG. 3. For example, layers of the ferroelectric material 314 may be deposited, selectively etched, and the conductive material 308 deposited into the etched regions.

At FIG. 6G, additional inductor layers are formed across the device. As noted above, in some cases, a fabrication process may include a fixed number of metallization layers, and inductors can be formed in some or all of those metallization layers.

At FIG. 6H, a carrier structure 640 is bonded to the front face of the device, e.g., to the front face of the inductors and ferroelectric material 314. In some embodiments, an oxide layer 606 or other form of bonding layer is deposited over the ferroelectric material 314 prior to attaching the carrier structure 640. The carrier structure 640 may be similar to any of the support structures described above.

At FIG. 6I, the device is flipped, and the support structure 620 is removed, e.g., by grinding. In some embodiments, a portion of the support structure 620 remains. Through-substrate vias (TSVs) may be formed through the remaining portion of the support structure 620.

At FIG. 6J, back end interconnects 304 and solder balls 302 are fabricated over the exposed side of the transistors 306, and a support structure 650 is coupled to the solder balls 302. The support structure 650 may be the support structure 210 shown in FIGS. 2-5. The device illustrated in FIG. 6J is similar to the device shown in FIG. 5 but flipped upside-down.

Example Devices

Arrangements with one or more integrated inductors as disclosed herein may be included in any suitable electronic device. FIGS. 7-10 illustrate various examples of devices and components that may include one or more integrated inductors as disclosed herein.

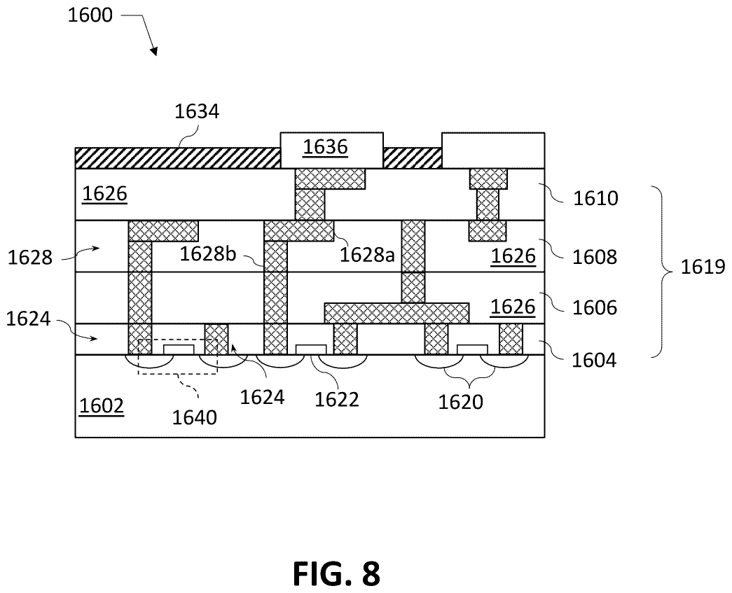

FIGS. 7A and 7B are top views of a wafer and dies that include one or more IC structures that may include one or more integrated inductors formed over the semiconductor devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-6, or any further embodiments of the IC structures described herein). After the fabrication of the semiconductor product is complete (e.g., after manufacture of one or more IC devices with one or more integrated inductors as described herein, included in a particular electronic component, e.g., in a computing device), the wafer 1500 may undergo a singulation process in which each of the dies 1502 is separated from one another to provide discrete “chips” of the semiconductor product. In particular, devices that include one or more integrated inductors as disclosed herein may take the form of the wafer 1500 (e.g., not singulated) or the form of the die 1502 (e.g., singulated). The die 1502 may include one or more transistors (e.g., one or more of the transistors 1640 of FIG. 8, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 8 is a cross-sectional side view of an IC device 1600 that may include one or more integrated inductors in accordance with any of the embodiments disclosed herein. The IC device 1600 may be formed on a substrate 1602 (e.g., the wafer 1500 of FIG. 7A) and may be included in a die (e.g., the die 1502 of FIG. 7B). The substrate 1602 may be any substrate as described herein. The substrate 1602 may be part of a singulated die (e.g., the dies 1502 of FIG. 7B) or a wafer (e.g., the wafer 1500 of FIG. 7A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more integrated inductors at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 8. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 8. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

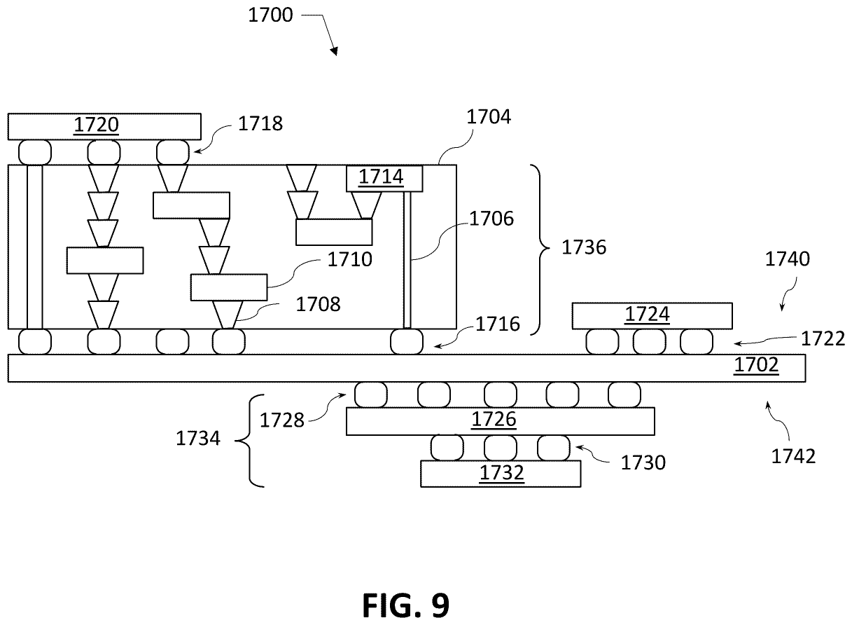

FIG. 9 is a cross-sectional side view of an IC device assembly 1700 that may include one or more integrated inductors in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7B), an IC device (e.g., the IC device 1600 of FIG. 8), or any other suitable component. In some embodiments, the IC package 1720 may include one or more integrated inductors, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example computing device 1800 that may include one or more components including one or more integrated inductors in accordance with any of the embodiments disclosed herein. For example, any suitable ones of the components of the computing device 1800 may include a die (e.g., the die 1502 (FIG. 7B)) having one or more integrated inductors. Any one or more of the components of the computing device 1800 may include, or be included in, an IC device 1600 (FIG. 8). Any one or more of the components of the computing device 1800 may include, or be included in, an IC device assembly 1700 (FIG. 9).

A number of components are illustrated in FIG. 10 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 10, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.

Example 1 provides an IC device including an interconnect region including a plurality of metal layers; a device layer including a plurality of transistors, the device layer over the interconnect region; and an inductor over a front side of the device layer, the inductor including a metal coil and a ferroelectric material inside the metal coil.

Example 2 provides the IC device of example 1, where the interconnect region includes a voltage input on a back side of the interconnect region, the back side on an opposite side of the interconnect region from the device layer.

Example 3 provides the IC device of example 2, where the voltage input is to receive a first voltage, and the inductor is to step down the first voltage to a second voltage having a lower amplitude than the first voltage.

Example 4 provides the IC device of any of examples 1 through 3, further including a support structure over the inductor.

Example 5 provides the IC device of any of examples 1 through 4, where the inductor is formed in a plurality of metallization layers over the device layer.

Example 6 provides the IC device of example 5, where the inductor includes a coil having a first side, a second side, and a third side, the second side coupled to the first side and the third side, and the second side extends in a direction substantially parallel to the front side of the device layer.

Example 7 provides the IC device of example 6, where the first side of the inductor extends in a direction substantially parallel to the front side of the device layer and substantially perpendicular to the second side of the inductor.

Example 8 provides the IC device of example 5, where the inductor includes a coil having a first side, a second side, and a third side, the second side coupled to the first side and the third side, and the second side extends in a direction substantially perpendicular to the front side of the device layer.

Example 9 provides the IC device of example 8, where the first side of the inductor extends in a direction substantially parallel to the front side of the device and substantially perpendicular to the second side of the inductor.

Example 10 provides the IC device of any of the preceding examples, where the inductor is over a first portion of the device layer, the IC device further including a dummy structure over a second portion of the device layer.

Example 11 provides an IC device including an interconnect region including a pad to receive a first voltage from a power source; a device region including a plurality of semiconductor devices; and an inductor, where the device region is between the inductor and the interconnect region, the inductor electrically is coupled to the pad to receive the first voltage, and the inductor is to step down the first voltage to a second voltage.

Example 12 provides the IC device of example 11, the IC device further including an internal power rail at the second voltage.

Example 13 provides the IC device of example 11 or 12, where the inductor is formed in a plurality of metallization layers over the device region.

Example 14 provides the IC device of any of examples 11 through 13, where the inductor includes at least one conductive coil and a ferroelectric material in a region surrounded by the conductive coil.

Example 15 provides the IC device of example 14, where the conductive coil has a first side, a second side, and a third side, the second side coupled to the first side and the third side, and the second side extends in a direction substantially parallel to a front side of the device region.

Example 16 provides the IC device of example 14, where the conductive coil has a first side, a second side, and a third side, the second side coupled to the first side and the third side, and the second side extends in a direction substantially perpendicular to a front side of the device region.

Example 17 provides the IC device of any of examples 11 through 16, where the inductor is over a first portion of the device region, the IC device further including a dummy structure over a second portion of the device region.

Example 18 provides a method for forming an IC device including forming a device layer including a plurality of transistors; forming an inductor over a first side of the device layer; and forming a plurality of interconnect layers over a second side of the device layer, the second side opposite the first side.

Example 19 provides the method of example 18, further including forming a pad over the plurality of interconnect layers, the pad electrically coupled to the inductor via the plurality of interconnect layers and the device layer.

Example 20 provides the method of example 18 or 19, where the inductor includes a conductive structure coiled around a ferroelectric material.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
an interconnect region comprising a plurality of metal layers;
a device layer comprising a plurality of transistors, the device layer over the interconnect region; and
an inductor over a front side of the device layer, the inductor comprising a metal coil and a ferroelectric material inside the metal coil.

2. The IC device of claim 1, wherein the interconnect region comprises a voltage input on a back side of the interconnect region, the back side on an opposite side of the interconnect region from the device layer.

3. The IC device of claim 2, wherein the voltage input is to receive a first voltage, and the inductor is to step down the first voltage to a second voltage having a lower amplitude than the first voltage.

4. The IC device of claim 1, further comprising a support structure over the inductor.

5. The IC device of claim 1, wherein the inductor is formed in a plurality of metallization layers over the device layer.

6. The IC device of claim 5, wherein the inductor comprises a coil having a first side, a second side, and a third side, the second side coupled to the first side and the third side, and the second side extends in a direction substantially parallel to the front side of the device layer.

7. The IC device of claim 6, wherein the first side of the inductor extends in a direction substantially parallel to the front side of the device layer and substantially perpendicular to the second side of the inductor.

8. The IC device of claim 5, wherein the inductor comprises a coil having a first side, a second side, and a third side, the second side coupled to the first side and the third side, and the second side extends in a direction substantially perpendicular to the front side of the device layer.

9. The IC device of claim 8, wherein the first side of the inductor extends in a direction substantially parallel to the front side of the device and substantially perpendicular to the second side of the inductor.

10. The IC device of claim 1, wherein the inductor is over a first portion of the device layer, the IC device further comprising a dummy structure over a second portion of the device layer.

11. An integrated circuit (IC) device comprising:
an interconnect region comprising a pad to receive a first voltage from a power source;
a device region comprising a plurality of semiconductor devices; and
an inductor, wherein the device region is between the inductor and the interconnect region, the inductor electrically is coupled to the pad to receive the first voltage, and the inductor is to step down the first voltage to a second voltage.

12. The IC device of claim 11, the IC device further comprising an internal power rail at the second voltage.

13. The IC device of claim 11, wherein the inductor is formed in a plurality of metallization layers over the device region.

14. The IC device of claim 11, wherein the inductor comprises at least one conductive coil and a ferroelectric material in a region surrounded by the conductive coil.

15. The IC device of claim 14, wherein the conductive coil has a first side, a second side, and a third side, the second side coupled to the first side and the third side, and the second side extends in a direction substantially parallel to a front side of the device region.

16. The IC device of claim 14, wherein the conductive coil has a first side, a second side, and a third side, the second side coupled to the first side and the third side, and the second side extends in a direction substantially perpendicular to a front side of the device region.

17. The IC device of claim 11, wherein the inductor is over a first portion of the device region, the IC device further comprising a dummy structure over a second portion of the device region.

18. A method for forming an integrated circuit (IC) device comprising:
forming a device layer comprising a plurality of transistors;
forming an inductor over a first side of the device layer; and
forming a plurality of interconnect layers over a second side of the device layer, the second side opposite the first side.

19. The method of claim 18, further comprising forming a pad over the plurality of interconnect layers, the pad electrically coupled to the inductor via the plurality of interconnect layers and the device layer.

20. The method of claim 18, wherein the inductor comprises a conductive structure coiled around a ferroelectric material.
